(19) United States
(12) Patent Application Publication
(10) Pub. No.: US 2008/0247219 A1
(43) Pub. Date: Oct. 9, 2008

(54) Resistive Random Access Memory Devices Including Sidewall Resistive Layers and Related Methods

(75) Inventors: Suk-Hun Choi, Gyeonggi-do (KR); In-Gyu Baek, Seoul (KR); Seong-Kyu Yun, Seoul (KR); Jong-Heun Lim, Seoul (KR); Chagn-Ki Hong, Gyeonggi-do (KR); Bo-Un Yoon, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/062,042

(22) Filed: Apr. 3, 2008

(30) Foreign Application Priority Data
Apr. 4, 2007 (KR) 2007-33084

(51) Int. Cl. G11C 11/00; H01C 17/00

(52) U.S. Cl. 365/148; 29/610.1

(57) ABSTRACT

A resistive random access memory (RRAM) device may include a first metal pattern on a substrate, a first insulating layer on the first metal pattern and on the substrate, an electrode, a second insulating layer on the first insulating layer, a resistive memory layer, and a second metal pattern. Portions of the first metal pattern may be between the substrate and the first insulating layer, and the first insulating layer may have a first opening therein exposing a portion of the first metal pattern. The electrode may be in the opening with the electrode being electrically coupled with the exposed portion of the first metal pattern. The first insulating layer may be between the second insulating layer and the substrate, and the second insulating layer may have a second opening therein exposing a portion of the electrode. The resistive memory layer may be on side faces of the second opening and on portions of the electrode, and the second metal pattern may be in the second opening with the resistive memory layer between the second metal pattern and the side faces of the second opening and between the second metal pattern and the electrode. Related methods are also discussed.

### RELATED APPLICATIONS

This application claims the benefit of priority under 35 U.S.C. § 119 to Korean Patent Application No. 2007-33084, filed on Apr. 4, 2007, in the Korean Intellectual Property Office (KIPO), the disclosure of which is herein incorporated by reference in its entirety.

### FIELD OF THE INVENTION

Embodiments of the present invention relate to electronic memory devices, and more particularly, to resistive random access memory devices and related methods.

### BACKGROUND

Various non-volatile memory devices have been studied for use in place of dynamic random access memories (DRAMs). Studies of non-volatile memory devices have been directed toward increased capacity, increased speed, reduced power consumption, etc.

Examples of the new non-volatile memory devices include magnetic random access memory (MRAM) devices, ferroelectric random access memory (FRAM) devices, phase-changeable random access memory (PRAM) devices, etc. In addition, resistive random access memory (RRAM) devices may use a phenomenon that a resistance is significantly changed by a specific electrical pulse.

An RRAM may have a structure where a variable resistor is interposed between electrodes. A resistance of the variable resistor may be increased or reduced in accordance with a voltage applied to the electrodes. More particularly, in a RRAM, the variable resistor may go to a reset state where the resistance is relatively high or a set state where the resistance is relatively low by applying a voltage or an electrical pulse to the electrodes at both ends of the variable resistor. The RRAM may be operated as a memory device using the different resistive states of the variable resistor.

Further, an RRAM may have a cross point structure configured to provide a single memory cell at intersections of digit and bit lines. Thus, since a single memory cell may be formed in a relatively small area, an RRAM may provide relatively high integration densities.

However, in a conventional RRAM having a cross point structure, a leakage current may flow through a memory cell at an adjacent cross point in addition to the memory cell of the cross point being programmed so that interference between memory cells may be generated. A conventional RRAM may also have relatively high power consumption.

### SUMMARY

According to some embodiments of the present invention, a resistive random access memory (RRAM) device may include a first metal pattern on a substrate, a first insulating layer on the first metal pattern and on the substrate, an electrode, a second insulating layer on the first insulating layer, a resistive memory layer, and a second metal pattern. Portions of the first metal pattern may be between the substrate and the first insulating layer, and the first insulating layer may have a first opening therein exposing a portion of the first metal pattern. The electrode may be in the opening with the electrode being electrically coupled with the exposed portion of the first metal pattern. The first insulating layer may be between the second insulating layer and the substrate, and the second insulating layer may have a second opening therein exposing a portion of the electrode. The resistive memory layer may be on side faces of the second opening and on portions of the electrode, and the second metal pattern may be in the second opening with the resistive memory layer between the second metal pattern and the side faces of the second opening and between the second metal pattern and the electrode.

The electrode may be a first electrode, and a second electrode may be in the second opening between the resistive memory layer and the second metal pattern. The second electrode may include a noble metal, and/or the second electrode may include a material selected from the group consisting of iridium, rubidium, platinum, tungsten, aluminum, and/or titanium nitride. The resistive memory layer may include a layer of a metal oxide such as nickel oxide, niobium oxide, titanium oxide, zirconium oxide, hafnium oxide, cobalt oxide, iron oxide, copper oxide, aluminum oxide, and/or chromium oxide.

A diode may be provided in the first opening so that the diode and the electrode are electrically coupled in series between the first metal pattern and the resistive memory layer. The diode, for example, may be a polysilicon diode defining a p-n junction, and the electrode may be defined as a doped region of polysilicon in the first opening spaced apart from the p-n junction.

In addition, a conductive barrier layer may be provided in the second opening between the resistive memory layer and the second metal pattern. The conductive barrier layer, for example, may include a layer of a metal and/or a metal nitride such as a layer of titanium and/or a layer of titanium nitride. Moreover, the electrode may include a noble metal, and/or the electrode may include a material selected from the group consisting of iridium, rubidium, platinum, tungsten, aluminum, and/or titanium nitride.

The first metal pattern may have a linear shape extending along a surface of the substrate in a first direction, and the first insulating layer may have a plurality of first openings exposing a plurality of spaced apart portions of the first metal pattern. The electrode may include a plurality of electrodes with each one of the plurality of electrodes being in a respective one of the plurality of first openings. The second insulating layer may have a plurality of second openings defining respective trenches with each of the plurality of trenches exposing a portion of a respective one of the plurality of electrodes and with each of the plurality of trenches extending in a second direction different than the first direction. The resistive memory layer may include a plurality of resistive memory layers with each of the plurality of the resistive memory layers being on side faces of a respective one of the trenches, and on a respective one of the plurality of electrodes. The second metal pattern may include a plurality of second metal patterns with each of the plurality of the second metal patterns being in a respective one of the trenches and extending in the second direction.

According to some other embodiments of the present invention, a method of forming a resistive random access memory (RRAM) device may include forming a first metal pattern on a substrate, and forming a first insulating layer on the first metal pattern and on the substrate. Portions of the first metal pattern may be between the substrate and the first insulating layer, and the first insulating layer may have a first opening therein exposing a portion of the first metal pattern. An electrode may be formed in the opening with the electrode being electrically coupled with the exposed portion of the first metal pattern. A second insulating layer may be formed on the first insulating layer with the first insulating layer between the second insulating layer and the substrate and with the second insulating layer having a second opening therein exposing a portion of the electrode. A resistive memory layer may be formed on side faces of the second opening and on portions of the electrode, and a second metal pattern may be formed in the second opening. The resistive memory layer may be between the second metal pattern and the side faces of the second opening, and the resistive memory layer may be between the second metal pattern and the electrode.

The electrode may be a first electrode, and a second electrode may be formed in the second opening between the resistive memory layer and the second metal pattern. The second electrode may include a noble metal and/or the second electrode may include a material selected from the group consisting of iridium, rubidium, platinum, tungsten, aluminum, and/or titanium nitride. The resistive memory layer may include a layer of a metal oxide such as nickel oxide, niobium oxide, titanium oxide, zirconium oxide, hafnium oxide, cobalt oxide, iron oxide, copper oxide, aluminum oxide, and/or chromium oxide.

After forming the first insulating layer, a diode may be formed in the first opening so that the diode and the electrode are electrically coupled in series between the first metal pattern and the resistive memory layer. The diode, for example, may be a polysilicon diode defining a p-n junction, and the electrode may be defined as a doped region of polysilicon in the first opening spaced apart from the p-n junction. Forming the diode may include forming a polysilicon layer in the first opening so that the polysilicon layer is recessed in the first opening relative to a surface of the first insulating layer opposite the substrate, and implanting impurities into the polysilicon layer to define a P-N junction in the polysilicon layer.

A conductive barrier layer may be formed in the second opening between the resistive memory layer and the second metal pattern. The conductive barrier layer may include a layer of a metal and/or a metal nitride such as a layer of titanium and/or a layer of titanium nitride. The electrode may include a noble metal, and/or the electrode may include a material selected from the group consisting of iridium, rubidium, platinum, tungsten, aluminum, and/or titanium nitride.

The first metal pattern may have a linear shape extending along a surface of the substrate in a first direction, and the first insulating layer may have a plurality of first openings exposing a plurality of spaced apart portions of the first metal pattern. The electrode may include a plurality of electrodes with each one of the plurality of electrodes being in a respective one of the plurality of first openings. The second insulating layer may have a plurality of second openings defining respective trenches with each of the plurality of trenches exposing a portion of a respective one of the plurality of electrodes and with each of the plurality of trenches extending in a second direction different than the first direction. The resistive memory layer may include a plurality of resistive memory layers with each of the plurality of the resistive memory layers being on side faces of a respective one of the trenches, and on a respective one of the plurality of electrodes. The second metal pattern may include a plurality of second metal patterns with each of the plurality of the second metal patterns being in a respective one of the trenches and extending in the second direction.

According to still other embodiments of the present invention, a resistive random access memory (RRAM) device may include first and second spaced apart metal patterns on a substrate with the first and second metal patterns extending along the substrate in a first direction. An insulating layer may be on the first and second spaced apart metal patterns and on the substrate with portions of the first and second spaced apart metal patterns between the insulating layer and the substrate. The insulating layer may also include a trench therein extending in a second direction different that the first direction so that the trench crosses the first and second spaced apart metal patterns. A resistive memory layer may be on side and bottom faces of the trench, and a third metal pattern may be in the trench with the resistive memory layer between the third metal pattern and the side and bottom faces of the trench. The resistive memory layer may be electrically coupled between the first and third metal patterns at an intersection thereof, and the resistive memory layer may be electrically coupled between the second and third metal patterns at an intersection thereof.

The resistive memory layer may include a metal oxide such as nickel oxide, niobium oxide, titanium oxide, zirconium oxide, hafnium oxide, cobalt oxide, iron oxide, copper oxide, aluminum oxide, and/or chromium oxide.

The insulating layer may be a first insulating layer, and a second insulating layer may be provided between the first insulating layer and the first and second metal patterns. The second insulating layer may include a first hole between the resistive memory layer and the first metal pattern and a second hole between the resistive memory layer and the second metal pattern. A first electrode in the first hole may provide electrical coupling between the first and third metal patterns, and a second electrode in the second hole may provide electrical coupling between the second and third metal patterns. A first diode in the first hole may be electrically coupled in series with the first electrode between the first and third metal patterns, and a second diode in the second hole may be electrically coupled in series with the second electrode between the second and third metal patterns.

According to some embodiments of the present invention, a relatively simple process to form a resistive random access memory device (RRAM) may be provided.

An RRAM in accordance with some embodiments of the present invention may include a first metal pattern, a first insulation interlayer pattern, a lower electrode pattern, a second insulation interlayer pattern, a resistive layer pattern, an upper electrode pattern, and a second metal pattern. The first metal pattern may be formed on a substrate, and the first insulation interlayer pattern may cover the first metal pattern. Further, the first insulation interlayer pattern may have a first opening partially exposing an upper face of the first metal pattern. The lower electrode pattern may be formed in the first opening, and the second insulation interlayer pattern may be formed on the lower electrode pattern and the first insulation interlayer pattern. Further, the second insulation interlayer pattern may have a second opening partially exposing an upper face of the lower electrode pattern. The resistive layer pattern may be formed on a side face and a bottom face of the second opening, and the upper electrode pattern may be formed on the resistive layer pattern. The second metal pattern may be formed on the upper electrode pattern to fill up the second opening.

The resistive layer pattern may include a metal oxide such as nickel oxide, niobium oxide, titanium oxide, zirconium oxide, hafnium oxide, cobalt oxide, iron oxide, copper oxide, aluminum oxide, chromium oxide, etc.

An RRAM in accordance with some other embodiments of the present invention may include a first metal pattern, a first insulation interlayer pattern, a lower electrode pattern, a second insulation interlayer pattern, a resistive layer pattern, an upper electrode pattern and a second metal pattern. The first metal pattern may be formed on a substrate, and the first metal pattern may have a linear shape extending along a first direction. The first insulation interlayer pattern may cover the first metal pattern, and the first insulation interlayer pattern may have a plurality of first openings partially exposing an upper face of the first metal pattern. The lower electrode pattern may be formed in the first opening, and the second insulation interlayer pattern may be formed on the lower electrode pattern and the first insulation interlayer pattern. The second insulation interlayer pattern may have a second opening extending along a second direction substantially perpendicular to the first direction to partially expose an upper face of the lower electrode pattern. The resistive layer pattern may be formed on a side face and a bottom face of the second opening, and the upper electrode pattern may be formed on the resistive layer pattern. The second metal pattern extending along the second direction may be formed on the upper electrode pattern to fill the second opening.

The RRAM may further include diodes formed in lower portions of the respective first openings and making contact with the first metal pattern to support the lower electrode pattern. The RRAM may further include a metal barrier layer pattern making contact with a side face and a bottom face of the lower electrode pattern. The resistive layer pattern may include a metal oxide such as nickel oxide, niobium oxide, titanium oxide, zirconium oxide, hafnium oxide, cobalt oxide, iron oxide, copper oxide, aluminum oxide, chromium oxide, etc. The upper electrode pattern may include iridium, rubidium, platinum, etc. Moreover, unit cells may be formed at cross points so that the RRAM may provide relatively high integration.

In a method of manufacturing an RRAM in accordance with still other embodiments of the present invention, a first metal pattern may be formed on a substrate, and a first insulation interlayer pattern may cover the first metal pattern. Here, the first insulation interlayer pattern may have a first opening partially exposing an upper face of the first metal pattern. A lower electrode pattern may be formed in the first opening, and a second insulation interlayer pattern may be formed on the lower electrode pattern and the first insulation interlayer pattern. Here, the second insulation interlayer pattern may have a second opening partially exposing an upper face of the lower electrode pattern. A resistive layer pattern may be formed on a side face and a bottom face of the second opening. An upper electrode pattern may be formed on the resistive layer pattern, and a second metal pattern may be formed on the upper electrode pattern to fill up the second opening.

The resistive layer pattern may include a metal oxide such as nickel oxide, niobium oxide, titanium oxide, zirconium oxide, hafnium oxide, cobalt oxide, iron oxide, copper oxide, aluminum oxide, chromium oxide, etc.

In a method of manufacturing an RRAM in accordance with yet still other embodiments of the present invention, a first metal pattern may be formed on a substrate, and the first metal pattern may have a linear shape extending along a first direction. A first insulation interlayer pattern may cover the first metal pattern, and the first insulation interlayer pattern may have a plurality of first openings partially exposing an upper face of the first metal pattern. A lower electrode pattern may be formed in the first opening. A second insulation interlayer pattern may be formed on the lower electrode pattern and the first insulation interlayer pattern. The second insulation interlayer pattern may have a second opening extending along a second direction substantially perpendicular to the first direction to partially expose an upper face of the lower electrode pattern. A resistive layer pattern may be formed on a side face and a bottom face of the second opening, and an upper electrode pattern may be formed on the resistive layer pattern. A second metal pattern extending along the second direction may be formed on the upper electrode pattern to fill the second opening.

The method may further include partially filling the first opening with a diode that makes contact with the first metal pattern, after forming the first insulation interlayer pattern. Forming the diode may include fully filling the first opening with a polysilicon layer, etching-back the polysilicon layer to form a polysilicon layer pattern partially filling the first opening, and implanting impurities into the polysilicon layer pattern.

The resistive layer pattern may include a metal oxide such as nickel oxide, niobium oxide, titanium oxide, zirconium oxide, hafnium oxide, cobalt oxide, iron oxide, copper oxide, aluminum oxide, chromium oxide, etc. The upper electrode pattern may include iridium, rubidium, platinum, etc.

The method may further include forming a metal barrier layer pattern that makes contact with a side face and a bottom face of the lower electrode pattern, before forming the lower electrode pattern.

According to some embodiments of the present invention, an RRAM having a relatively high capacity may be manufactured using a relatively simple process and/or failures generated during manufacture of the RRAM may be reduced.

### BRIEF DESCRIPTION OF THE DRAWINGS

The above and other features and advantages of the present invention will become readily apparent by reference to the following detailed description when considered in conjunction with the accompanying drawings, wherein:

FIG. 1 is a cross-sectional view illustrating a unit cell of a resistive random access memory (RRAM) in accordance with some embodiments of the present invention;

FIGS. 2 to 5 are cross-sectional views illustrating operations of manufacturing the unit cell of the RRAM in FIG. 1 in accordance with embodiments of the present invention;

FIG. 6 is a perspective view illustrating an RRAM in accordance with other embodiments of the present invention; and

FIGS. 7 to 14 are cross-sectional views illustrating operations of manufacturing the RRAM in FIG. 6 in accordance with embodiments of the present invention.

### DETAILED DESCRIPTION

The present invention is described more fully hereinafter with reference to the accompanying drawings, in which examples of embodiments of the present invention are shown. The present invention may, however, be embodied in many different forms and should not be construed as limited to the examples of embodiments set forth herein. Rather, these examples of embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

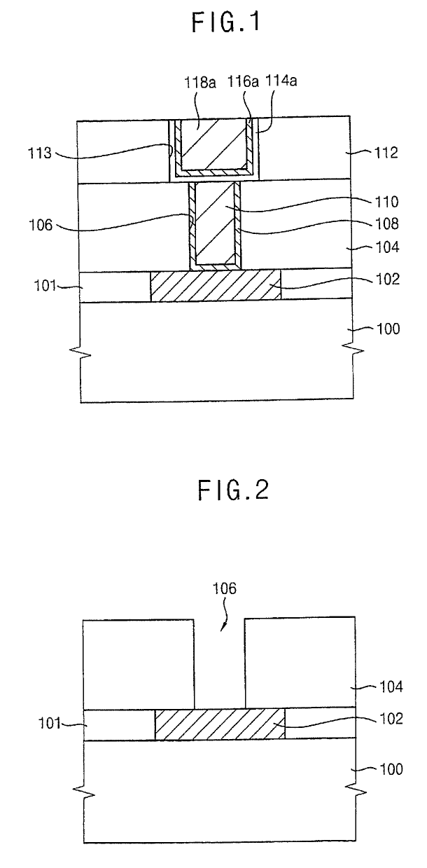

FIG. 1 is a cross-sectional view illustrating a unit cell of a resistive random access memory (RRAM) in accordance with first embodiments of the present invention. More particularly, the RRAM of FIG. 1 includes a supporting substrate 100, a first metal pattern 102, a first insulation interlayer pattern 104, a lower electrode pattern 110, a second insulation interlayer pattern 112, a resistive layer pattern 114a, an upper electrode pattern 116a, and a second metal pattern 118a.

The supporting substrate 100 may be a substrate including a semiconductor material such as single crystalline silicon. The supporting substrate 100, for example, may include a semiconductor substrate and an insulation layer formed on the semiconductor substrate.

The first metal pattern 102 may be formed on the supporting substrate 100, and the first metal pattern 102 may have a relatively high conductivity. Examples of a material that may be used for the first metal pattern 102 may include metals such as tungsten, aluminum, titanium nitride, etc. Although not illustrated in drawings, a hard mask pattern including silicon oxynitride may be formed on the first metal pattern 102.

A lower insulation interlayer pattern 101 may be formed between the first metal pattern 102 and the hard mask pattern. In FIG. 1, the lower insulation interlayer pattern 101 may include silicon oxide.

The first insulation interlayer pattern 104 may cover the first metal pattern 102, and the first insulation interlayer pattern 104 may have a relatively flat upper face. The first insulation interlayer pattern 104 may include silicon oxide. The first insulation interlayer pattern 104 may have a first opening 106 partially exposing an upper face of the first metal pattern 102. A metal barrier layer pattern 108 may be formed on bottom and side faces of the first opening 106.

The first opening 106 may be filled with the lower electrode pattern 110. The lower electrode pattern 110 may be electrically connected to the first metal pattern 102. The lower electrode pattern 110 may include a metal or metal nitride such as tungsten, aluminum, titanium nitride, etc. In addition, or in the alternative, the lower electrode pattern 110 may include a noble metal such as iridium, rubidium, platinum, etc. A metal, a metal nitride, and/or a noble metal may be used alone or in combinations thereof. When the lower electrode pattern 110 (making direct contact with the resistive layer pattern 114a) includes a noble metal, electrical characteristics of the RRAM may be improved. Further, the lower electrode pattern 110 may have an upper face that is substantially coplanar with that of the first insulation interlayer pattern 104.

The second insulation interlayer pattern 112 may be formed on the lower electrode pattern 110 and the first insulation interlayer pattern 104. The second insulation interlayer pattern 112 may have a second opening 113 exposing the upper face of the lower electrode pattern 110.

Here, the electrical characteristics of the RRAM may be improved by providing a relatively small contact area between the resistive layer pattern 114a and the lower electrode pattern 110. Thus, the upper face of the lower electrode pattern 110 may be only partially exposed through a bottom face of the second opening 113.

The resistive layer pattern 114a may be formed on side and bottom faces of the second opening 113. The resistive layer pattern 114a may include a metal oxide having two components such as nickel oxide, niobium oxide, titanium oxide, zirconium oxide, hafnium oxide, cobalt oxide, iron oxide, copper oxide, aluminum oxide, chromium oxide, etc. These metal oxides may be used alone or in a combination(s) thereof.

The upper electrode pattern 116a may be formed on the resistive layer pattern 114a. The upper electrode pattern 116a may include a noble metal such as iridium, rubidium, platinum, etc. In addition, or in the alternative, the upper electrode pattern 116a may include a metal and/or a metal nitride such as tungsten, aluminum, titanium nitride, etc. Here, any one of the upper electrode pattern 116a and/or the lower electrode pattern 110 (which make contact with the resistive layer pattern 114a) may include a noble metal. The second metal pattern 118a may be formed on the upper electrode pattern 116a to fill the second opening 113. Examples of a material that may be used for the second metal pattern 118a may include tungsten, aluminum, titanium nitride, etc.

FIGS. 2 to 5 are cross-sectional views illustrating a method of manufacturing the unit cell of the RRAM of FIG. 1.

Referring to FIG. 2, the supporting substrate 100 is prepared. The supporting substrate 100 may include a substrate including a semiconductor material such as single crystal silicon. For example, the supporting substrate 100 may include a semiconductor substrate and an insulation layer formed on the semiconductor substrate.

A first metal layer (not shown) may be formed on the supporting substrate 100, and the first metal layer may include a material having a relatively high conductivity. The first metal layer may be etched using a dry etching process. Examples of a material that may be used for the first metal layer may include tungsten, aluminum, titanium nitride, etc.

A hard mask layer (not shown) may be formed on the first metal layer, and the hard mask layer may include silicon oxide. The hard mask layer may be patterned to form a hard mask pattern (not shown). The first metal layer may be etched using the hard mask pattern as an etching mask to form the first metal pattern 102.

The lower insulation interlayer pattern 101 may be formed on the first metal pattern 102 and the hard mask pattern. The lower insulation interlayer pattern 101 may include silicon oxide formed using a chemical vapor deposition (CVD) process.

The lower insulation interlayer pattern 101 may be planarized using a chemical mechanical polishing (CMP) process to expose an upper face of the hard mask pattern. When the hard mask pattern is used as a polishing stop layer, the lower insulation layer pattern 101 and the hard mask pattern may be provided with relatively flat and coplanar upper faces.

A first insulation interlayer (not shown) is formed on the first metal pattern 102 and the lower insulation interlayer pattern 101. The first insulation interlayer may be formed using silicon oxide by a CVD process.

The first insulation interlayer and the hard mask pattern may be partially etched to form the first insulation interlayer pattern 104 having the first opening 106. The upper face of the first metal pattern 102 is exposed through the bottom of the first opening 106.

Alternatively, after forming the first metal pattern 102, the first insulation interlayer may cover the first metal pattern 102 and an upper face of the first insulation interlayer may then be planarized. In this case, the first insulation interlayer may be partially etched to form the first insulation interlayer pattern 104 having the first opening 106.

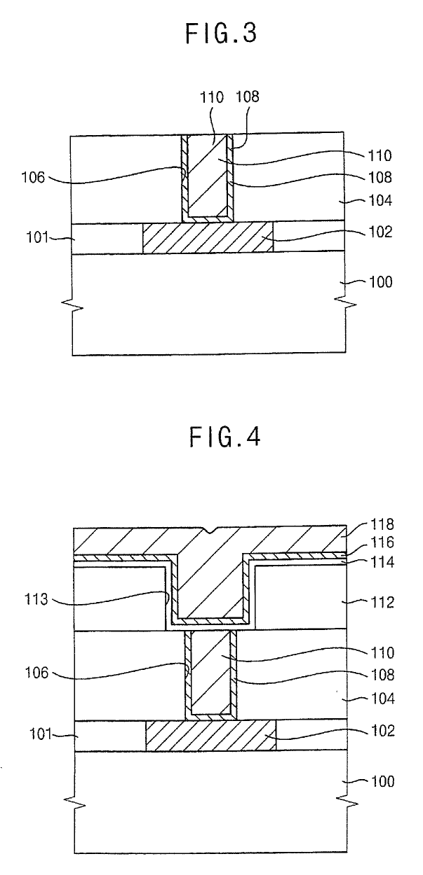

Referring to FIG. 3, a metal barrier layer (not shown) may be formed on side and bottom faces of the first opening 106. The metal barrier layer may include a titanium layer and a titanium nitride layer.

The first opening 106 may be completely filled with a lower electrode layer (not shown). Examples of a conductive material that may be used for the lower electrode layer may include a metal and/or a metal nitride such as tungsten, aluminum, titanium nitride, etc. and/or a noble metal such as iridium, rubidium, platinum, etc. A noble metal can be used alone or in combination with one or more other noble metals.

The lower electrode layer and the metal barrier layer may be partially removed using a CMP process until the upper face of the first insulation interlayer pattern 104 is exposed to form the metal barrier layer pattern 108 and the lower electrode pattern 110.

Referring to FIG. 4, a second insulation interlayer (not shown) may be formed on the lower electrode pattern 110 and the first insulation interlayer pattern 104. The second insulation interlayer may include silicon oxide formed using a CVD process.

The second insulation interlayer may be partially etched to form the second insulation interlayer pattern 112 having the second opening 113 that exposes the lower electrode pattern 110.

A resistive layer 114 may be formed on side and bottom faces of the second opening 113 and on an upper face of the second insulation interlayer 112.

The lower electrode pattern 110 may have an upper face substantially coplanar with that of the first insulation interlayer pattern 104. The resistive layer may include a metal oxide having two components. Examples of a material that may be used for the resistive layer pattern 114a may include nickel oxide, niobium oxide, titanium oxide, zirconium oxide, hafnium oxide, cobalt oxide, iron oxide, copper oxide, aluminum oxide, chromium oxide, etc. One or more of these materials can be used alone or in combinations thereof.

A noble metal or other metal may be formed on the resistive layer 114 to form an upper electrode layer 116. Examples of the noble metal that may be used for the upper electrode layer 116 may include iridium, rubidium, platinum, etc. Examples of other metals that may be used for the upper electrode layer 116 may include tungsten, aluminum, titanium nitride, etc. The metals may be used alone or in combinations thereof.

Here, any one of the upper electrode layer 116 and/or the lower electrode pattern 110 (which make contact with the resistive layer 114) may include a noble metal.

A second metal layer 118 may be formed on the upper electrode layer 116 to fill the second opening 113. The second metal layer 118 may include a conductive material providing good gap-filling characteristics. Examples of a material that may be used for the second metal layer 118 may include tungsten, aluminum, titanium nitride, etc.

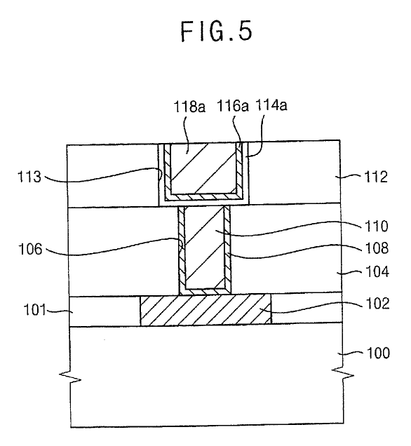

Referring to FIG. 5, the second metal layer 118, the upper electrode layer 116 and the resistive layer 114 may be partially removed until the upper face of the second insulation interlayer pattern 112 is exposed to form the resistive layer pattern 114a, the upper electrode pattern 116a and the second metal pattern 118a in the second opening 113. The partial removal of the second metal layer 118, the upper electrode layer 116 and the resistive layer 114 may be performed using a CMP process.

The CMP process may be carried out to allow portions of the lower electrode layer to remain in the first opening to form the lower electrode pattern. Thus, it may not be necessary to anisotropically etch the lower electrode layer to form the lower electrode pattern. As a result, failures generated when the metal barrier layer remains or is excessively etched during anisotropic etching of the lower electrode layer may be reduced.

Further, the CMP process may be performed to allow the resistive layer, the upper electrode layer and the second metal layer to remain in the second opening to form the resistive layer pattern, the upper electrode pattern, and the second metal pattern. Thus, it may not be necessary to anisotropically etch the resistive layer, the upper electrode layer and the second metal layer to form the resistive layer pattern, the upper electrode pattern, and the second metal pattern, respectively. As a result, etching damage may be reduced at the resistive layer pattern, the upper electrode pattern, and the second metal pattern. Further, polymers adhering to side faces of the above-mentioned patterns during the etching processes may be reduced.

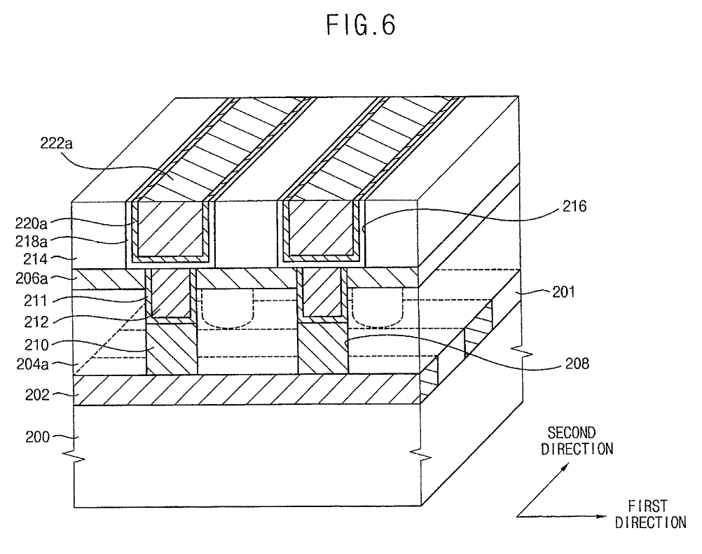

FIG. 6 is a perspective view illustrating an RRAM in accordance with second embodiments of the present invention. The RRAM of FIG. 6 may include a supporting substrate 200, first metal patterns 202, a first insulation interlayer pattern 204a, a diode 210, a lower electrode pattern 212, a second insulation interlayer pattern 214, a resistive layer pattern 218a, an upper electrode pattern 220a and a second metal pattern 222a.

The supporting substrate 200 may be a substrate including a semiconductor material such as single crystal silicon. For example, the supporting substrate 100 may include a semiconductor substrate and an insulation layer formed on the semiconductor substrate.

The first metal patterns 202 may be formed on the supporting substrate 200. In this example embodiment, the first metal patterns 202 may have linear shapes extending along a first direction. Further, the first metal patterns 202 may be arranged in parallel with each other, and the first metal patterns 202 may have relatively high conductivity. Examples of a material that may be used for the first metal patterns 102 may include tungsten, aluminum, titanium nitride, etc. Although not illustrated in the drawings, a hard mask pattern (not shown) including silicon oxynitride may be formed on the first metal patterns 202.

A lower insulation interlayer pattern 201 may be formed on portions of the supporting substrate 200 between the first metal patterns 202 and the hard mask pattern. In this example embodiment, the lower insulation interlayer pattern 201 may include silicon oxide.

The first insulation interlayer pattern 204a covers the first metal patterns 202, and the first insulation interlayer pattern 204a may have a relatively flat upper face. The first insulation interlayer pattern 204a, for example, may include silicon oxide. The first insulation interlayer pattern 204a has first openings 208 exposing portions of an upper face of the first metal patterns 202. Each of the first openings 208 may have a shape substantially similar to that of a contact hole. Furthermore, the first openings 208 may be regularly arranged with substantially constant intervals therebetween.

An etching stop layer pattern 206a may be formed on the first insulation interlayer pattern 204a. The etching stop layer pattern 206a may include an insulation material having a high etching selectivity with respect to silicon oxide. For example, the etching stop layer pattern 206a may include silicon nitride, silicon oxynitride, etc.

The first openings 208 may be partially filled with respective diodes 210. Each diode 210 makes contact with a respective one of the first metal patterns 202. Each diode 210 may include a first polysilicon layer doped with n-type impurities, and a second polysilicon layer doped with p-type impurities on the first polysilicon layer defining a P-N junction therebetween.

Each diode 210 may allow a current to flow along a forward direction in accordance with data in the respective memory cells of the RRAM. Thus, when a selected memory cell is programmed, current may be blocked from flowing through a non-selected memory cell adjacent to the selected memory cell along a backward direction. A direction of flow of the current may thus be set as only one direction due to the diode 210 so that data in non-selected memory cells may remain unchanged while a selected memory cell is programmed.

Moreover, selection transistors used to select memory cells of the RRAM may be omitted by providing the diodes 210. A horizontal area where a single memory cell is formed may thus be reduced.

A metal barrier layer pattern 211 may be formed on bottom and side faces of the first openings 208. The metal barrier layer pattern 211 may serve as an adhesion layer enhancing adhesion strength of a lower electrode pattern 212 with respect to side and bottom faces of the first openings 208.

The lower electrode pattern 212 may be formed on the metal barrier layer pattern 211. The first openings 208 may be filled with the lower electrode pattern 212. Each lower electrode pattern 212 may be electrically connected to a respective diode 210.

The lower electrode pattern 212 may include a metal and/or a metal nitride such as tungsten, aluminum, titanium nitride, etc. Additional examples of metals that may be used for the lower electrode pattern 212 may include noble metals such as iridium, rubidium, platinum, etc. Further, the lower electrode pattern 212 may have a structure where a first metal layer and a noble metal layer (different than the first metal layer) are sequentially stacked. Moreover, each lower electrode pattern 212 may have an upper face that is substantially coplanar with that of the etching stop layer pattern 206a.

The second insulation interlayer pattern 214 may be formed on the lower electrode pattern 212, on the first insulation interlayer pattern 204a, and on the etching stop layer pattern 206a. The second insulation interlayer pattern 214 may have second openings 216 exposing upper faces of the respective lower electrode pattern 212. The second openings 216 may also extend (as trenches) along a second direction substantially perpendicular to the first direction of the first metal patterns 202. The lower electrode patterns 212 may thus be exposed through the second openings 216.

Electrical characteristics of the RRAM of FIG. 6 may be improved by reducing a contact area between the resistive layer patterns 218a and the respective lower electrode patterns 212. Upper faces of the lower electrode patterns 212 may thus be only partially exposed through bottom faces of the respective second openings 216. Further, the second insulation interlayer pattern 214 may include silicon oxide.

The resistive layer pattern 218a is formed on side and bottom faces of the second openings 216. As shown in FIG. 6, the resistive layer pattern 218a may have a U-shape making contact with the lower electrode pattern 212.

The resistive layer pattern 218a may include a metal oxide having two components. Examples of a material that may be used as the resistive layer pattern 218a may include nickel oxide, niobium oxide, titanium oxide, zirconium oxide, hafnium oxide, cobalt oxide, iron oxide, copper oxide, aluminum oxide, chromium oxide, etc. These metal oxides can be used alone or in a combination or combinations thereof.

As discussed above, the metal oxide having the two components may have operational characteristics that are independent at different areas of the resistive layer pattern 218a. Although the resistive layer pattern 218a may be formed on a very small area, the operational characteristics of different RRAM cells may not be significantly influenced by other RRAM cells of the same resistive layer pattern 218a. The metal oxide having the two components may be suitable for the resistive layer pattern 218a in highly integrated RRAMs.

The resistive layer patterns 218a may be continuous along the trench-like second openings 216, and thus, each respective layer pattern 218a may be in contact with multiple lower electrode patterns 212. Portions of a resistive layer pattern 218a in contact with different lower electrode patterns 212, however, may operative independently as different memory storage elements.

The upper electrode pattern 220a may be formed on the resistive layer pattern 218a. The upper electrode pattern 220a may have a U-shape substantially similar to that of the resistive layer pattern 218a. The upper electrode pattern 220a may include a noble metal and/or a non-noble metal, and/or metal nitrides. Examples of noble metals that may be used include iridium, rubidium, platinum, etc. Examples of non-noble metals and/or metal nitrides that may be used include tungsten, aluminum, titanium nitride, etc.

Here, any one of the upper electrode patterns 220a and/or the lower electrode patterns 212, which make contact with the resistive layer patterns 218a, may include a noble metal.

Second metal patterns 222a may be formed on the upper electrode patterns 220a to fill the second openings 216. The second metal patterns 222a may have a linear shape extending in the second direction. Examples of materials that may be used for the second metal patterns 222a may include tungsten, aluminum, titanium nitride, etc.

The resistive layer patterns 218a may have a cross-sectional U-shape extending along side and bottom faces of the second openings 216. However, since the resistive layer patterns 218a may have a relatively high resistance, a filamentary path may be locally generated at a portion of the resistive layer pattern 218a making contact with the lower electrode pattern 212 to locally change a resistance of the resistive layer pattern 218a. Therefore, although the resistive layer patterns 218a may be continuous between adjacent cells, interference between the adjacent cells may not result.

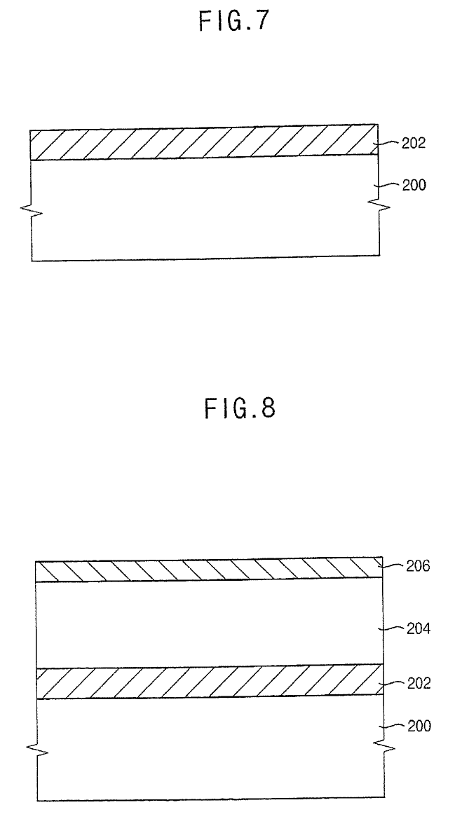

FIGS. 7 to 14 are cross-sectional views illustrating operations of manufacturing the RRAM in FIG. 6.

Referring to FIG. 7, the supporting substrate 200 is prepared. The supporting substrate 200 may be a substrate including a semiconductor material such as single crystal silicon. For example, the supporting substrate 200 may include a semiconductor substrate and an insulation layer formed on the semiconductor substrate.

The first metal patterns 202 may be formed on the supporting substrate 200. The first metal patterns 202 may have a linear shape extending in the first direction. Further, lower insulation interlayer patterns (not shown) may be formed on portions of the substrate 200 between the first metal patterns 202.

Hereinafter, operations used to form the first metal patterns 202 are discussed in greater in detail. A first metal layer (not shown) may be formed on the supporting substrate 200. The first metal layer may include a material having a relatively high conductivity. Examples of a material that may be used for the first metal layer may include metals and/or metal nitrides such as tungsten, aluminum, titanium nitride, etc.

A hard mask layer (not shown) may be formed on the first metal layer, and the hard mask layer may include silicon oxide. The hard mask layer is patterned to form hard mask patterns (not shown). The hard mask patterns may have a linear shape extending along the first direction, and the hard mask patterns may be arranged in parallel with each other. The first metal layer may then be etched using the hard mask patterns as an etching mask to form the first metal patterns 202.

The lower insulation interlayer pattern 201 (shown in FIG. 6) is formed on portions of the substrate 200 between the first metal patterns 202 and the hard mask pattern. A lower insulation layer may be formed on the substrate, on the hard mask pattern, and on the first metal patterns 202, and the lower insulation layer may include silicon oxide formed using chemical vapor deposition (CVD).

The lower insulation layer may be planarized using a chemical mechanical polishing (CMP) process to expose an upper face of the hard mask pattern to thereby form the lower insulation interlayer patterns 201. When the hard mask pattern is used as a polishing stop layer, the lower insulation layer pattern 201 and the hard mask pattern may be provided with relatively flat upper faces. The hard mask patterns may then be removed.

Referring to FIG. 8, a first insulation interlayer 204 may be formed on the first metal patterns 202 and the lower insulation interlayer pattern 201. The first insulation interlayer 204 may be a layer of silicon oxide formed using CVD.

An etching stop layer 206 may be formed on the first insulation interlayer 204. The etching stop layer 206 may include an insulation material having a high etching selectivity with respect to silicon oxide. The etching stop layer 206 may include silicon nitride and/or silicon oxynitride formed using CVD.

Diodes 210 and lower electrode patterns 212 may be formed in first openings 208 through the first insulation interlayer pattern 204 and the etching stop layer 206 as discussed below. Thus, the first insulation interlayer 204 may have a sufficient thickness to allow the first openings 208 to have a depth sufficient for the diode 210 and the lower electrode pattern 212 to be formed.

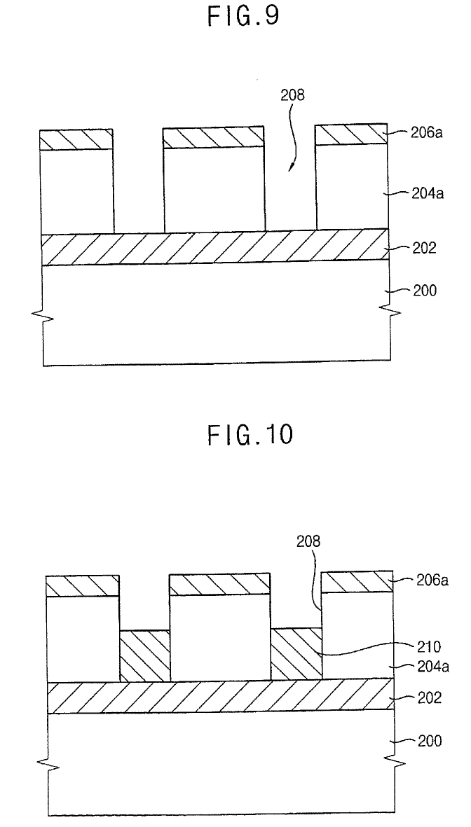

Referring to FIG. 9, a mask pattern (not shown) having openings maybe formed on the etching stop layer 206. The first insulation interlayer 204 and the etching stop layer 206 may be sequentially etched to form the first openings 208. Portions of upper faces of the first metal patterns 202 may be exposed through bottom faces of the first openings 208. The first openings 208 may be arranged with substantially constant intervals therebetween. The etching stop layer pattern 206a and the first insulation interlayer pattern 204a through which the first openings 208 are formed may thus be provided.

Referring to FIG. 10, a polysilicon layer (not shown) maybe formed on the etching stop layer pattern 206a to fill the first openings 208. The polysilicon layer may then be anisotropically etched to form polysilicon layer patterns partially filling the first openings 208. Here, a portion of the polysilicon layer on the etching stop layer pattern 206a may be completely removed by the anisotropic etching process.

Impurities may then be implanted into the polysilicon layer patterns. Any one of n-type impurities and p-type impurities may be implanted into the polysilicon layer pattern. Impurities having a conductive type contrary to that of impurities implanted into the polysilicon layer pattern may then be implanted into the polysilicon layer patterns. Here, the n-type impurities and the p-type impurities may have different implantation depths so that the n-type impurities and the p-type impurities define a P-N junction substantially parallel with a surface of substrate 200. As a result, P-N diodes 210 making contact with the first metal patterns 202 may be formed using ion implantations.

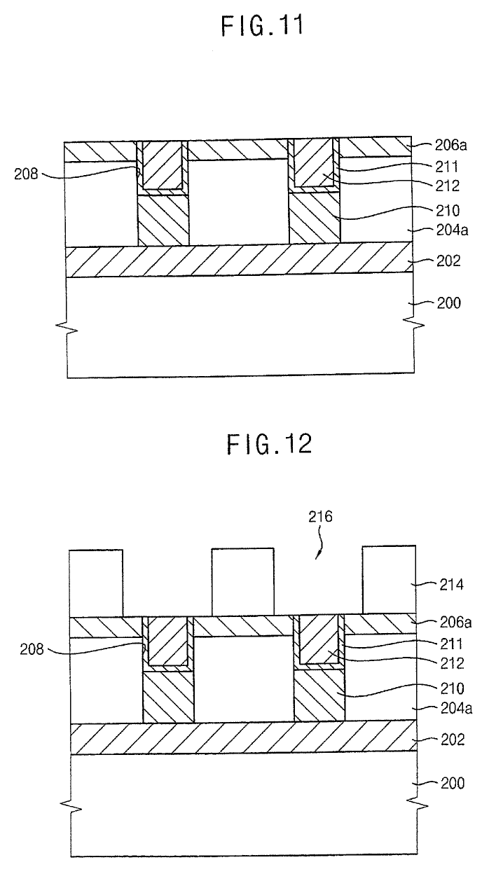

Referring to FIG. 11, a metal barrier layer (not shown) may be formed on side faces of the first openings 208, on upper faces of the diodes 210, and on an upper face of the etching stop layer pattern 206a. The metal barrier layer may include a titanium layer and a titanium nitride layer.

The first openings 208 may be fully filled with a lower electrode layer (not shown). The lower electrode layer may include a material having good gap-filling characteristics to reduce generation of voids in the first openings 208.

Examples of a conductive material that may be used for the lower electrode layer may include metals and/or metal nitrides such as tungsten, aluminum, titanium nitride, etc. Additional examples of a material that may be used for the lower electrode layer may include a noble metal such as iridium, rubidium, platinum, etc. Further, the lower electrode layer may have a structure where a metal and a noble metal (e.g., two different metals) are sequentially stacked. When the lower electrode layer includes a noble metal, the RRAM may have improved electrical characteristics.

The lower electrode layer and the metal barrier layer may be partially removed using a CMP process until the upper face of the etching stop layer pattern 206a is exposed to form the metal barrier layer patterns 211 and the lower electrode patterns 212 on the diodes 210 in the first openings 208. The lower electrode pattern 212 may have an upper face that is substantially coplanar with that of the etching stop layer pattern 206a.

Referring to FIG. 12, a second insulation interlayer 214 may be formed on the lower electrode pattern 212 and the first insulation interlayer pattern 204a. The second insulation interlayer 214 may be a layer of silicon oxide formed using CVD.

The resistive layer patterns 218a, the upper electrode patterns 220a, and the second metal patterns 222a maybe formed in the second insulation interlayer 214 as discussed below. The second insulation interlayer 214 may have a thickness sufficient to receive the resistive layer patterns 218a, the upper electrode patterns 220a, and the second metal patterns 222a.

Mask patterns (not shown) may be formed on the second insulation interlayer 214. Here, the mask patterns may have a linear shape extending along the second direction substantially perpendicular to the first direction. Further, the lower electrode patterns 212 may be under exposed portions of the second insulation interlayer 214 between the mask patterns.

The second insulation interlayer 214 may be selectively etched using the mask pattern to form the second openings 216 that expose the lower electrode patterns 212 repeatedly arranged along the second direction. Here, the second openings 216 extend as trenches along the second direction.

Electrical characteristics of the RRAM may be improved by reducing a contact area between the resistive layer patterns 218a and the lower electrode patterns 212. Upper faces of the lower electrode patterns 212 may thus be partially exposed through a bottom face of the second openings 216. The second insulation interlayer pattern 214 having the second openings 216 may thus be formed.

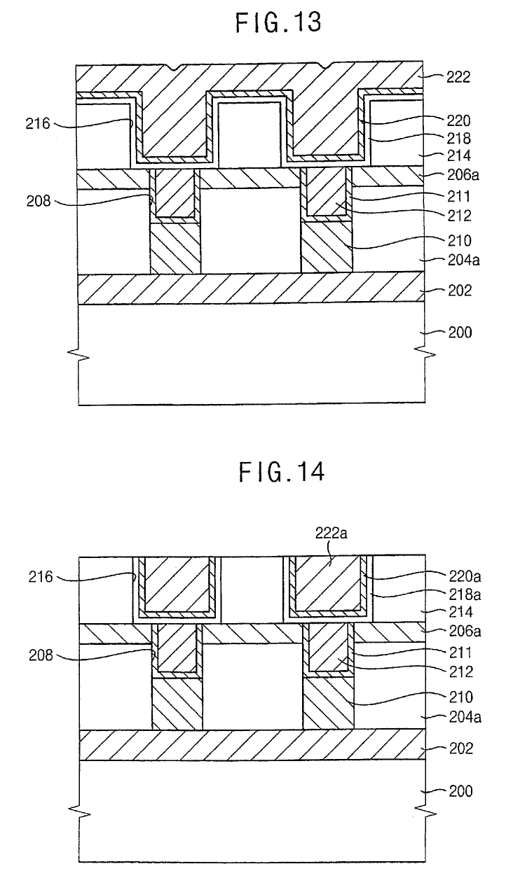

Referring to FIG. 13, a resistive layer 218 may be formed on side and bottom faces of the second openings 216 and on an upper face of the second insulation interlayer pattern 214. The resistive layer 218 may include a metal oxide having two components. Examples of a material that may be used for the resistive layer 218 may include metal oxides such as nickel oxide, niobium oxide, titanium oxide, zirconium oxide, hafnium oxide, cobalt oxide, iron oxide, copper oxide, aluminum oxide, chromium oxide, etc. One or more of these metal oxides may be used alone or in combinations thereof.

A noble metal, a non-noble metal, and/or a metal nitride may be formed on the resistive layer 218 to provide an upper electrode layer 220. Examples of the non-noble metals and/or metal nitrides that may be used for the upper electrode layer 220 may include iridium, rubidium, platinum, etc. Examples of the metal that may be used for the upper electrode layer 220 may include tungsten, aluminum, titanium nitride, etc. The non-noble metals and/or the noble metals may be used alone or in combinations thereof.

Any one of the upper electrode layer 220 and/or the lower electrode pattern 212, which make contact with the resistive layer 218, may include a noble metal.

A second metal layer 222 is formed on the upper electrode layer 220 to fill the second openings 216. The second metal layer 222 may include a conductive material providing good gap-filling characteristics. Examples of a material that may be used for the second metal layer 222 may include a metal and/or a metal nitride such as tungsten, aluminum, titanium nitride, etc.

Referring to FIG. 14, the second metal layer 222, the upper electrode layer 220 and the resistive layer 218 may be partially removed until the upper face of the second insulation interlayer pattern 214 is exposed to form the resistive layer patterns 218a, the upper electrode patterns 220a, and the second metal patterns 222a in the second openings 216. The second metal layer 222, the upper electrode layer 220, and the resistive layer may be partially removed using a chemical mechanical polishing process.

The upper electrode pattern 220a and the resistive layer pattern 218a may have a cross-sectional U-shape extending along side and bottom faces of the second openings 216. Further, the upper electrode 220a and the resistive layer pattern 218a may extend along the second direction perpendicular to the first direction.

The RRAM of FIGS. 6 and 14 may thus provide unit memory cells at a cross points where the first metal patterns 202 and the second metal patterns 222a intersect.

According to embodiments of FIGS. 6-14, it may not be necessary to perform a dry etching process to form the resistive layer pattern, the upper electrode pattern, and/or the second metal pattern. Thus, process failures caused by dry etching may be reduced.

Further, the resistive layer pattern, the upper electrode pattern, and the second metal pattern may be formed using a single CMP process. Since the upper face of the second metal pattern is substantially coplanar with that of the second insulation interlayer pattern, an additional planarization process may not be required even if an additional insulation interlayer is substantially formed on the second insulation interlayer pattern. As a result, the RRAM may be manufactured using relatively simple processes.

According to some embodiments of the present invention, an RRAM having relatively high capacities may be manufactured by relatively simple processes. Further, failures generated during manufacture of the RRAM may be reduced. Furthermore, unit cells of an RRAM formed according to embodiments of the present invention may be located at the cross points so that relatively high integration densities may be provided.

The foregoing is illustrative of embodiments of the present invention and is not to be construed as limiting thereof. Although examples of particular embodiments of the present invention have been described, those skilled in the art will readily appreciate that many modifications are possible without materially departing from the novel teachings and advantages of this invention. Accordingly, all such modifications are intended to be included within the scope of the present invention as defined in the claims. Therefore, it is to be understood that the foregoing is illustrative of embodiments of the present invention and that the present invention is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A resistive random access memory (RRAM) device comprising:
a substrate;
a first metal pattern on the substrate;
a first insulating layer on the first metal pattern and on the substrate, wherein portions of the first metal pattern are between the substrate and the first insulating layer and wherein the first insulating layer has a first opening therein exposing a portion of the first metal pattern;
an electrode in the opening wherein the electrode is electrically coupled with the exposed portion of the first metal pattern;
a second insulating layer on the first insulating layer wherein the first insulating layer is between the second insulating layer and the substrate and wherein the second insulating layer has a second opening therein exposing a portion of the electrode;
a resistive memory layer on side faces of the second opening and on portions of the electrode;
and a second metal pattern in the second opening wherein the resistive memory layer is between the second metal pattern and the side faces of the second opening and wherein the resistive memory layer is between the second metal pattern and the electrode.

2. An RRAM device according to claim 1 wherein the electrode comprises a first electrode, the RRAM device further comprising:
a second electrode in the second opening between the resistive memory layer and the second metal pattern.

3. An RRAM device according to claim 2 wherein the second electrode comprises a noble metal.

4. An RRAM device according to claim 2 wherein the second electrode comprises a material selected from the group consisting of iridium, rubidium, platinum, tungsten, aluminum, and/or titanium nitride.

5. An RRAM device according to claim 1 wherein the resistive memory layer comprises a layer of a metal oxide.

6. An RRAM device according to claim 5 wherein the metal oxide is selected from the group consisting of nickel oxide, niobium oxide, titanium oxide, zirconium oxide, hafnium oxide, cobalt oxide, iron oxide, copper oxide, aluminum oxide, and/or chromium oxide.

7. An RRAM device according to claim 1 further comprising:
a diode in the first opening so that the diode and the electrode are electrically coupled in series between the first metal pattern and the resistive memory layer.

8. An RRAM device according to claim 1 further comprising:
a conductive barrier layer in the second opening between the resistive memory layer and the second metal pattern.

9. An RRAM device according to claim 1 wherein the electrode comprises a noble metal.

10. An RRAM device according to claim 1 wherein the electrode comprises a material selected from the group consisting of iridium, rubidium, platinum, tungsten, aluminum, and/or titanium nitride.

11. An RRAM device according to claim 1,
wherein the first metal pattern has a linear shape extending along a surface of the substrate in a first direction,
wherein the first insulating layer has a plurality of first openings exposing a plurality of spaced apart portions of the first metal pattern,
wherein the electrode comprises a plurality of electrodes with each one of the plurality of electrodes being in a respective one of the plurality of first openings,
wherein the second insulating layer has a plurality of second openings defining respective trenches with each of the plurality of trenches exposing a portion of a respective one of the plurality of electrodes with each of the plurality of trenches extending in a second direction different than the first direction,
wherein the resistive memory layer comprises a plurality of resistive memory layers with each of the plurality of the resistive memory layers being on side faces of a respective one of the trenches, and on a respective one of the plurality of electrodes, and
wherein the second metal pattern comprises a plurality of second metal patterns with each of the plurality of the second metal patterns being in a respective one of the trenches and extending in the second direction.

12. A method of forming a resistive random access memory (RRAM) device, the method comprising:
forming a first metal pattern on a substrate;
forming a first insulating layer on the first metal pattern and on the substrate, wherein portions of the first metal pattern are between the substrate and the first insulating layer and wherein the first insulating layer has a first opening therein exposing a portion of the first metal pattern;
forming an electrode in the opening wherein the electrode is electrically coupled with the exposed portion of the first metal pattern;
forming a second insulating layer on the first insulating layer wherein the first insulating layer is between the second insulating layer and the substrate and wherein the second insulating layer has a second opening therein exposing a portion of the electrode;
forming a resistive memory layer on side faces of the second opening and on portions of the electrode; and
forming a second metal pattern in the second opening wherein the resistive memory layer is between the second metal pattern and the side faces of the second opening and wherein the resistive memory layer is between the second metal pattern and the electrode.

13. A method according to claim 12 wherein the electrode comprises a first electrode, the method further comprising:
forming a second electrode in the second opening between the resistive memory layer and the second metal pattern.

14. A method according to claim 13 wherein the second electrode comprises a noble metal.

15. A method according to claim 13 wherein the second electrode comprises a material selected from the group consisting of iridium, rubidium, platinum, tungsten, aluminum, and/or titanium nitride.

16. A method according to claim 12 wherein the resistive memory layer comprises a layer of a metal oxide.

17. A method according to claim 16 wherein the metal oxide is selected from the group consisting of nickel oxide, niobium oxide, titanium oxide, zirconium oxide, hafnium oxide, cobalt oxide, iron oxide, copper oxide, aluminum oxide, and/or chromium oxide.

18. A method according to claim 12 further comprising:
after forming the first insulating layer, forming a diode in the first opening so that the diode and the electrode are electrically coupled in series between the first metal pattern and the resistive memory layer.

19. A method according to claim 18 wherein forming the diode includes,
forming a polysilicon layer in the first opening so that the polysilicon layer is recessed in the first opening relative to a surface of the first insulating layer opposite the substrate, and
implanting impurities into the polysilicon layer to define a P-N junction in the polysilicon layer.

20. A method according to claim 12 further comprising:
forming a conductive barrier layer in the second opening between the resistive memory layer and the second metal pattern.

21. A method according to claim 12 wherein the electrode comprises a noble metal.

22. A method according to claim 12 wherein the electrode comprises a material selected from the group consisting of iridium, rubidium, platinum, tungsten, aluminum, and/or titanium nitride.

23. A method according to claim 12,
wherein the first metal pattern has a linear shape extending along a surface of the substrate in a first direction,
wherein the first insulating layer has a plurality of first openings exposing a plurality of spaced apart portions of the first metal pattern,
wherein the electrode comprises a plurality of electrodes with each one of the plurality of electrodes being in a respective one of the plurality of first openings,
wherein the second insulating layer has a plurality of second openings defining respective trenches with each of the plurality of trenches exposing a portion of a respective one of the plurality of electrodes with each of the plurality of trenches extending in a second direction different than the first direction,
wherein the resistive memory layer comprises a plurality of resistive memory layers with each of the plurality of the resistive memory layers being on side faces of a respective one of the trenches, and on a respective one of the plurality of electrodes, and
wherein the second metal pattern comprises a plurality of second metal patterns with each of the plurality of the second metal patterns being in a respective one of the trenches and extending in the second direction.

24. A resistive random access memory (RRAM) device comprising:
a substrate;
first and second spaced apart metal patterns on the substrate wherein the first and second metal patterns extend along the substrate in a first direction;
an insulating layer on the first and second spaced apart metal patterns and on the substrate wherein portions of the first and second spaced apart metal patterns are between the insulating layer and the substrate, and wherein the insulating layer includes a trench therein extending in a second direction different that the first direction so that the trench crosses the first and second spaced apart metal patterns;
a resistive memory layer on side and bottom faces of the trench; and
a third metal pattern in the trench wherein the resistive memory layer is between the third metal pattern and the side and bottom faces of the trench, wherein the resistive memory layer is electrically coupled between the first and third metal patterns at an intersection thereof, and wherein the resistive memory layer is electrically coupled between the second and third metal patterns at an intersection thereof.

25. An RRAM according to claim 24 wherein the resistive memory layer comprises a metal oxide.

26. An RRAM according to claim 24 wherein the insulating layer comprises a first insulating layer, the RRAM further comprising:
a second insulating layer between the first insulating layer and the first and second metal patterns, wherein the second insulating layer includes a first hole between resistive memory layer and the first metal pattern and a second hole between the resistive memory layer and the second metal pattern;
a first electrode in the first hole providing electrical coupling between the first and third metal patterns; and
a second electrode in the second hole providing electrical coupling between the second and third metal patterns.

27. An RRAM according to claim 26 further comprising:
a first diode in the first hole electrically coupled in series with the first electrode between the first and third metal patterns; and
a second diode in the second hole electrically coupled in series with the second electrode between the second and third metal patterns.
